(19) United States
(12) Patent Application Publication
(10) Pub. No.: US 2007/0090408 A1
(43) Pub. Date: Apr. 26, 2007

(54) Narrow-body multiple-gate FET with dominant body transistor for high performance

(76) Inventors: Amlan Majumdar, Portland, OR (US); Suman Datta, Beaverton, OR (US); Brian S. Doyle, Portland, OR (US); Jack Kavalieros, Portland, OR (US); Justin K. Brask, Portland, OR (US); Matthew V. Metz, Hillsboro, OR (US); Marko Radosavljevic, Beaverton, OR (US); Been-Yih Jin, Lake Oswego, OR (US); Robert S. Chau, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/240,487

(22) Filed: Sep. 29, 2005

(51) Int. Cl. H01L 29/76

(52) U.S. Cl. 257/213

(57) ABSTRACT

A field-effect transistor for a narrow-body, multiple-gate transistor such as a FinFET, tri-gate or Ω-FET is described. The corners of the channel region disposed beneath the gate are rounded n, for instance, oxidation steps, to reduce the comer effect associated with conduction initiating in the corners of the channel region.

### FIELD OF THE INVENTION

The invention relates to the field of field-effect transistors (FETs).

### PRIOR ART AND RELATED ART

Narrow-body multiple-gate transistors, such as FinFETs, tri-gate FETs, and gate Ω-FETs, have good short channel effect including low subthreshold slope and low drain-induced barrier lowering characteristics. The comers of the channel region define what may be referred to as a “comer transistor” which turns on before the main body of the channel region, particularly if the body doping is high and the comers are sharp. Where the transistor is dominated by comer effect, they have low I_{OFF}. However, since the body transistor has a higher threshold than the comer transistor, a low gate overdrive, and hence, a low I_{ON} for the overall transistor results. This problem is discussed subsequently in conjunction with FIGS. 1 and 2.

Examples of transistors having reduced bodies along with tri-gate structures are shown in US 2004/0036127. Other multi-gate transistors are delta-doped transistors formed in lightly doped or undoped epitaxial layers grown on a heavily doped substrate. See, for instance, “Metal Gate Transistor with Epitaxial Source and Drain Regions,” application Ser. No. 10/955,669, filed Sep. 29, 2004, assigned to the assignee of the present application. One structure for providing a more completely wrapped around gate is described in “Nonplanar Semiconductor Device with Partially or Fully Wrapped Around Gate Electrode and Methods of Fabrication,” U.S. patent application Ser. No. 10/607,769, filed Jun. 27, 2003, also assigned to the assignee of the present application.

### BRIEF DESCRIPTION OF THE DRAWINGS

FIG. 1 is a plot illustrating the electron density in the comer of a channel region.

FIG. 2 is a graph illustrating the percent of charge in the comers (Q_{c}) of a channel region compared to the total charge (Q_{T}) for a range of doping levels.

FIG. 3A is a perspective view of a semiconductor body formed on a bulk substrate.

FIG. 3B is a perspective view of a semiconductor body formed on a buried oxide layer (BOX).

FIG. 4A is a cross-sectional elevation view of the comer of the semiconductor bodies of FIGS. 3A and 3B, generally in the region of the circles 4-4.

FIG. 4B illustrates the comer of the semiconductor body of FIG. 4A after an oxidation step.

FIG. 4C illustrates the comer of the semiconductor body of FIG. 4B after a etching step.

FIG. 4D illustrates the semiconductor body of FIG. 4C after a second oxidation step.

FIG. 4E illustrates the semiconductor body of FIG. 4D after a second etching step.

FIG. 5A is a cross-sectional elevation view of a completed transistor for the semiconductor body of FIG. 3B with the comers rounded.

FIG. 5B illustrates the transistor of FIG. 5A when viewed from a perpendicular plane to the view of FIG. 5A.

FIG. 6 is a graph illustrating charge accumulated in the corners (Q_{c}) compared to a total charge (Q_{T}) in the channel region of a transistor for different corner rounding (R_{C}).

### DETAILED DESCRIPTION

A transistor and a method of fabricating the transistor is described. In the following description, numerous specific details are set forth such as specific materials, doping levels and radii of curvature. It will be apparent to one skilled in the art, that the present invention may be practiced without these specific details. In other instances, well-known fabrication steps are not described in detail in order to not unnecessarily obscure the present invention.

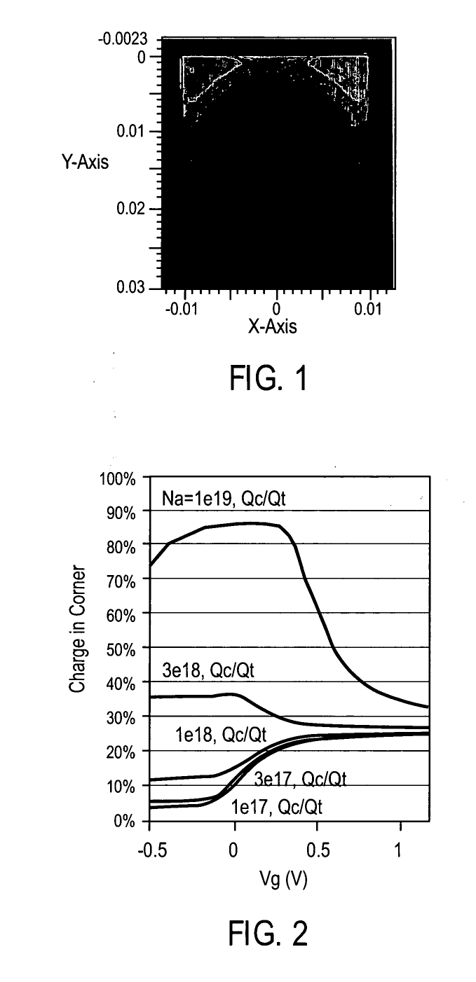

Referring to FIG. 1, the electron density in a channel region of an FET having opposite sides and an upper surface with corners defined at the intersection of the upper surface and sides is illustrated. The lighter regions of the plot indicate higher electron density when compared to the darker regions. The plot is for a silicon body with a polysilicon gate and a silicon dioxide gate insulation, with a gate voltage of 0.2 volts and a channel region doping to a level of 1×10¹⁹ atoms cm⁻³. As can be seen, more charge accumulates in the corners of the channel than in the center of the body at this subthreshold voltage. It is apparent from this figure that the corner transistor will turn on before the body transistor. Since the body transistor has a higher threshold than the corner transistor, this leads to low gate overdrive, and hence, a lower I_{ON}.

The doping in the channel region of a narrow-body transistor can be lowered without lowering the threshold voltage to an unmanageable level by using a high-k gate dielectric and a metal gate to target the threshold voltage. For example, the channel doping can be lowered below 5×10¹⁷ atoms cm⁻³ for mid-gap metal gates such as TiN. This, of course, would not be possible for FETs with a polysilicon/SiO₂ gate stacks because lowering the body doping to these low levels results in devices with very low threshold voltages.

Simulation results shown in FIG. 2 again indicate that, for the polysilicon/SiO₂ NMOS transistor doped to 1×10¹⁹ atoms cm⁻³, the inversion charge in the subthreshold region builds up in the comers (the uppermost curve in the diagram of FIG. 2). The remaining plots indicate that if the doping level is reduced (e.g. 3×10¹⁸ atoms cm⁻³ or lower), the percent of charge in the comers (Q_{c}) compared to the total charge (Q_{T}) is reduced in the subthreshold region. This has the effect of moving from a comer transistor to a “body transistor” realizable with a high-k gate dielectric and a metal gate. For all the curves of FIG. 2, the radius of curvature (R_{C}) for the comer is 0 nm, that is, a sharp corner.

As will be discussed, by rounding the corners at least in the channel region, a body transistor, as opposed to a comer transistor, may be realized. Moreover, by combining the lower doping in the channel region, which necessitates the high-k dielectric and a metal gate, along with a radius of curvature (R_{C}) for the corners of for instance, 4 nm or more, both good short channel effect, low I_{OFF} and high I_{ON} are achievable.

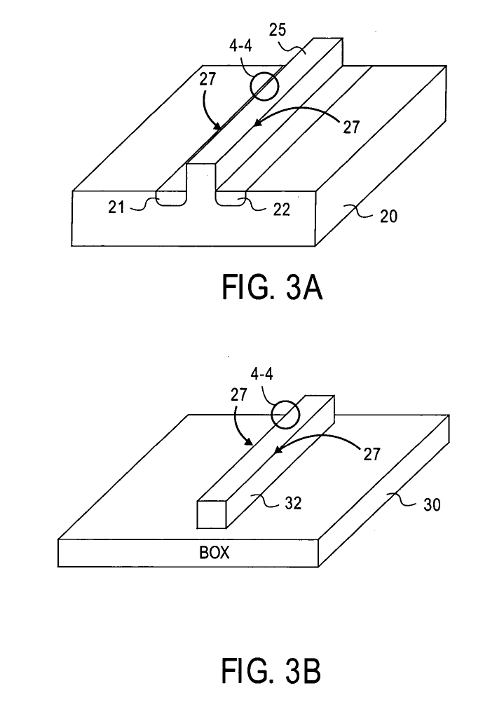

Two semiconductor bodies, such as silicon bodies, having sharp corners are illustrated in FIGS. 3A and 3B. In FIG. 3A, a substrate 20 such as a bulk monocrystalline silicon substrate is shown. A raised silicon body 25 is formed from the substrate 20 using one of a number of processing techniques. For instance, isolation regions 21 and 22 may be formed in the silicon substrate 20, followed by epitaxial growth to form the body 25. Alternatively, after spaced-apart isolation regions 21 and 22 are formed on the planar surface, these isolation regions are etched to define the body 25. In FIG. 3B the body 32 is fabricated from, for instance, a monocrystalline silicon layer disposed on the BOX 30. This silicon-on-insulation (SOI) substrate is well known in the semiconductor industry. By way of example, the SOI substrate is fabricated by bonding the BOX 30 and the layer from which the body 32 is etched onto an underlying substrate (not illustrated). Other techniques are known for forming an SOI substrate including, for instance, the implantation of oxygen in a silicon substrate to form a BOX. Other semiconductor materials other than silicon may also be used such as gallium arsenide.

Both the bodies 25 and 32 are used to form FETs. A gate, insulated from the body, is formed on the upper surface as well as the sides of the bodies to define a channel region in the body. Source and drain regions are typically implanted in alignment with a gate structure or a dummy gate structure where a replacement gate process is used. Most often spacers are used to define the main part of the source and drain regions.

The bodies of FIGS. 3A and 3B, as a result of typical processing, have comers 27. The comers are defined by the intersection of perpendicular surfaces, specifically, the upper surface intersecting the sides of the body. These comers, in the channel region, of the body accumulate charge forming the comer transistor, as discussed. In contrast, charge accumulates more uniformly throughout the body in a body transistor.

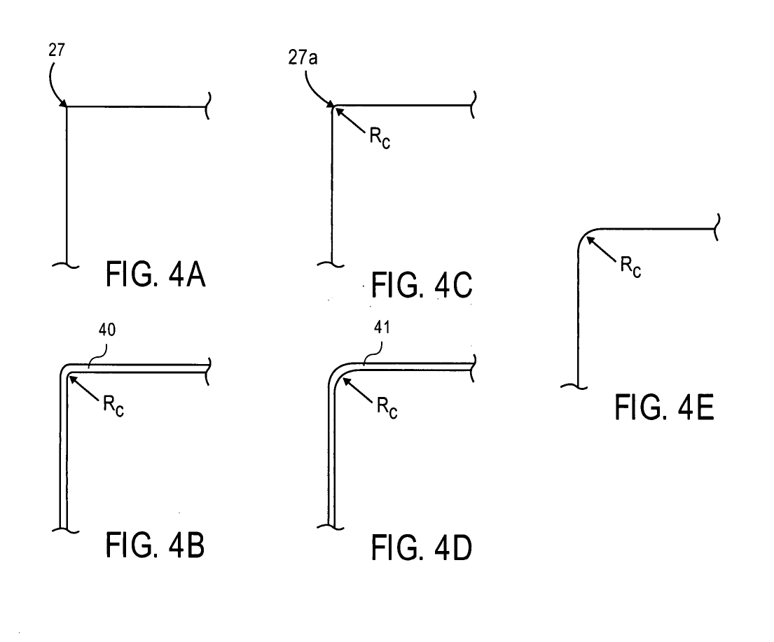

As mentioned earlier, there is benefit in rounding the comers since it reduces the comer effect. Moreover, a rounded comer can be more reliably fabricated than a sharp corner. In FIG. 4A, the comer 27 of the bodies 25 and 32 is shown in a cross-sectional, elevation view. To round the comer 27, an ordinary oxidation step is used. For instance, silicon can be oxidized in a wet or dry atmosphere in the presence of oxygen to form silicon dioxide, shown as the grown silicon dioxide layer 40 in FIG. 4B. In so doing, the comer of the semiconductor body becomes rounded, essentially eroding the comer 27. A wet etchant can then be used to remove the oxide 40, leaving the rounded comer 27a shown in FIG. 4C. The radius of curvature in FIG. 4C is shown as R_{C}. As will be discussed later, R_{C} should be approximately 4.0 nm or greater for a typical body. With current processing, the typical body shown in FIGS. 3A and 3B has a height in the range of 20 nm and a width in the range of 20 nm. An R_{C} of 4 nm provides a rounded comer without rounding off the entire body. On the other hand, an R_{C} of, for instance 10 nm, with a total body width of 20 nm, would provide a rounding of the entire structure and a significant reduction in the area of the channel region.

Suitable etchants for removal of the grown SiO₂ include but are not limited to phosphoric acid (H₃PO₄), hydrofluoric acid (HF), buffered HF, hydrochloric acid (HCl), nitric acid (HNO₃), acetic acid (CH₃COOH), alcohols, potassium permanganate (KMnO₄), ammonium fluoride (NH₄F), and others, as would be listed in known wet chemical etching references such as Thin Film Processes, Academic Press (1978), edited by John L. Vossen and Wemer Kem. Mixtures of these and other etchant chemicals are also conventionally used.

It may be that after a single oxidation step such as shown in FIG. 4B, R_{C} will not be large enough, for instance, it may only be 2 nm. When that occurs, a second oxidation step may be used as shown in FIG. 4D where another oxide layer 41 is grown on the body, and then etched to provide the rounded comer 27b of FIG. 4E. The oxidation steps may be repeated as many times as needed to provide the desired R_{C}.

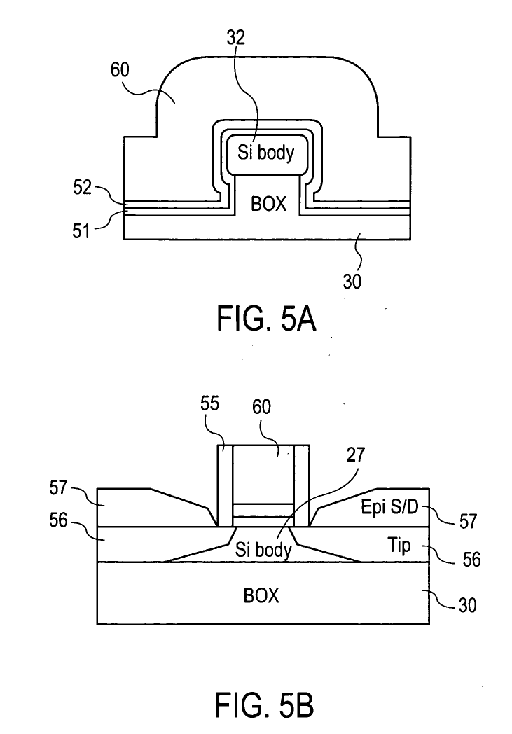

Following the rounding of the comers of the body, the fabrication of the FET is continued as is known in the art. Typically, first a dummy gate structure is fabricated followed by the formation of spacers after an initial tip implant for the source and drain regions. Then, the main source and drain regions are formed in some cases by the growth of a doped epitaxial layer. For one embodiment using the body 32 of FIG. 3B, the resultant FET is shown in FIGS. 5A and 5B. Again, the BOX 30 is present along with the tip implanted portion of the body 56. The epitaxial source and drain regions 57 are also shown along with the spacers 55, note the rounded comers of the body 32 best seen in FIG. 5A.

Once the dummy gate structure is removed in a replacement gate process, a gate dielectric 51 is formed on exposed surfaces which includes the exposed sides and top surfaces of the body 32. The gate dielectric has a high dielectric constant (k), such as a metal oxide dielectric, for instance, HfO₂ or ZrO₂ or other high k dielectrics, such as PZT or BST. The gate dielectric may be formed by any well-known technique such as atomic layer deposition (ALD) or chemical vapor deposition (CVD). Alternately, the gate dielectric may be a grown dielectric. For instance, the gate dielectric 51, may be a silicon dioxide film grown with a wet or dry oxidation process to a thickness between 5-50 Å.

Following this, a gate electrode (metal) layer 52 is formed over the gate dielectric layer 51. The gate electrode layer 52 may be formed by blanket deposition of a suitable gate electrode material. In one embodiment, a gate electrode material comprises a metal film such as tungsten, tantalum, titanium and/or nitrides and alloys thereof. For the n channel transistors, a work function in the range of 3.9 to 4.6 eV may be used. For the p channel transistors, a work function of 4.6 to 5.2 eV may be used. Accordingly, for substrates with both n channel and p channel transistors, two separate metal deposition processes may need to be used. Only approximately 100 Å of the metal needs to be formed through ALD to set the work function. The remainder of the gate may be formed of polysilicon, such as shown by polysilicon 60.

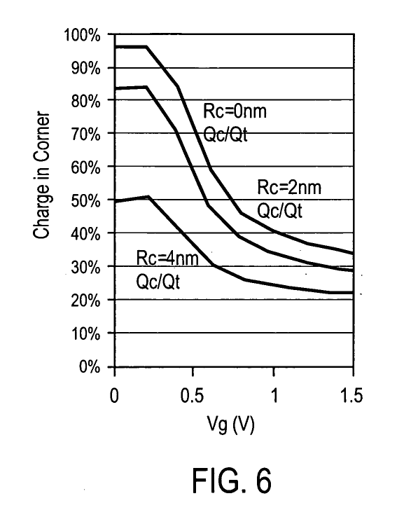

The effect of the rounding is demonstrated by the simulations shown in FIG. 6. The percent of charge in the comer compared to the total charge is represented along the ordinate with gate voltage along the abscissa. All the plots in FIG. 6 are for a body doping of 1×10¹⁹ atoms cm⁻³. With a square comer (R_{C}=0 nm), charge readily accumulates in the comer, particularly at the subthreshold voltages. With R_{C}=2 nm, some improvement is achieved, but there is still considerable charge accumulating in the comer. With R_{C}=4 nm, substantially less charge (50% or less) accumulates in the comer at the subthreshold voltages. This improves as R_{C} is increased, however, as mentioned, R_{C} should remain at no more than approximately ¼^{th} the width of the gate to prevent an overall rounding of the body.

By combining, as mentioned, both the rounding with R_{C} equal to approximately 4 nm or more, and by reducing the body doping to 3×10¹⁸ atoms cm⁻³ or lower, and using this in conjunction with a high-k dielectric and metal gate, a substantially improved transistor results. With this combination, no more than 30% of the total subthreshold charge accumulates in the comers of the FET.

What is claimed is:

1. A field-effect transistor comprising:
a channel region in a semiconductor body having at least an upper surface and two sides defining corners between the sides and upper surface, the corners being rounded and having a radius of curvature of approximately 4 nm or greater; and
a gate insulated from and disposed about the channel region.

2. The transistor defined by claim 1, wherein the gate is insulated from the channel region by a high-k dielectric, and wherein the gate comprises metal.

3. The transistor defined by claim 2, wherein the channel region is lightly doped.

4. The transistor defined by claim 3, wherein the doping level of the channel region is 3×10¹⁸ atoms cm⁻³, or less.

5. The transistor defined by claim 4, wherein the semiconductor body comprises silicon.

6. The transistor defined by claim 5, wherein the semiconductor body extends from a bulk silicon substrate.

7. The transistor defined by claim 5, wherein the semiconductor body is disposed on a buried oxide layer.

8. A transistor comprising:
a semiconductor body having opposite sides and an upper surface, the body having rounded corners between the upper surface and the opposite sides, the comers having a radius of approximately 4.0 nm or more, the body having a channel region disposed between a source and a drain region, the channel region being doped to a level of 3×10¹⁸ atoms cm⁻³ or less;
a high-k gate insulation disposed on the body about the channel region; and
a metal gate disposed on the gate insulation.

9. The transistor defined by claim 8, wherein the body is formed on a bulk monocrystalline substrate.

10. The transistor defined by claim 8, wherein the semiconductor body is formed on a buried oxide layer.

11. A transistor comprising:
a semiconductor body having opposite sides and an upper surface and a channel region disposed between a source and a drain region, the body having rounded comers between the upper surface and the opposite sides, the comers being rounded such that no more than 30% of total charge in the channel region is disposed in the comers at a subthreshold gate voltage, the channel region being doped to a level of 3×10¹⁸ atoms cm⁻³ or less;
a high-k gate insulation disposed on the body over the channel region; and
a metal gate disposed over the gate insulation.

12. The transistor defined by claim 11, wherein the body is formed on a bulk monocrystalline substrate.

13. The transistor defined by claim 11, wherein the body is formed on a buried oxide layer.

14. A method for fabricating a transistor on a bulk semiconductor substrate or on a semiconductor-on-insulation substrate comprising:
(a) forming a silicon body having an upper surface and opposite sides, thereby defining comer regions between the upper surface and sides;
(b) growing an oxide layer on the body;
(c) wet etching the body, thereby rounding the comers; and
(d) repeating (b) and (c), if the comer regions are not rounded to approximately 4.0 nm or more.

15. The method defined by claim 14, wherein the body comprises silicon.

16. The method defined by claim 14, wherein the doping level of the body in a channel region is 3×10¹⁸ atoms cm⁻³ or less.

17. The method defined by claim 16, including the forming of a high-k insulating layer over the channel region.

18. The method defined by claim 17, including the forming of a metal gate over the insulating layer.

19. The method defined by claim 14, including forming a high-k insulating layer over a channel region in the body.

20. The method defined by claim 19, including the formation of a metal gate over the insulating layer.
